(19) United States
(12) Patent Application Publication
(10) Pub. No.: US 2008/0160447 A1
(43) Pub. Date: Jul. 3, 2008

(54) Photopolymer Printing Plate Precursor

(76) Inventors: Willi-Kurt Gries, Mainz-Kastel (DE); Marc Van Damme, Bonheiden (BE); Frank Vangaever, St. Michiels Brugge (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(21) Appl. No.: 10/573,233

(22) PCT Filed: Sep. 1, 2004
(86) PCT No.: PCT/EP2004/051986

§ 371 Date: Jun. 15, 2006

(30) Foreign Application Priority Data
Sep. 22, 2003 (EP) 03103498.6

(51) Int. Cl. G03F 7/004; G03F 7/12

(52) U.S. Cl. 430/281.1; 430/302

(57) ABSTRACT

A photopolymer printing plate precursor is disclosed comprising in this order a photosensitive coating and a protective coating on a support, wherein said photosensitive coating comprises a composition that is photopolymerizable upon absorption of light, said composition comprising a binder, a polymerizable compound, a sensitizer and a photoinitiator, and wherein said protective coating comprises one or more types of polyvinylalcohol, characterized in that said photoinitiator is a hexaaryl-bisimidazole compound and the mean saponification degree of all the polyvinylalcohols which are used in the protective coating is less than 93 mol-%. Said printing plate precursor has high speed and a good pre-heat latitude.

### FIELD OF THE INVENTION

The present invention relates to a photopolymer printing plate precursor comprising in this order a photosensitive coating and a protective coating on a support. The invention also relates to a method of making a lithographic printing plate therewith, and to the use of one or more types of poly(vinyl alcohols) in the protective overcoat, to improve the pre-heat latitude of a printing plate precursor.

### BACKGROUND OF THE INVENTION

In lithographic printing, a so-called printing master such as a printing plate is mounted on a cylinder of the printing press. The master carries a lithographic image on its surface and a printed copy is obtained by applying ink to said image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e.: water-accepting, ink-repelling) areas. In so-called “driographic” printing, the lithographic image consists of ink-accepting and ink-adhesive (ink-repelling) areas and during driographic printing, only ink is supplied to the master.

Printing masters are generally obtained by the so-called computer-to-film (CtF) method, wherein various pre-press steps such as typeface selection, scanning, color separation, screening, trapping, layout and imposition are accomplished digitally and each color selection is transferred to graphic arts film using an image-setter. After processing, the film can be used as a mask for the exposure of an imaging material called plate precursor and after plate processing, a printing plate is obtained which can be used as a master. Since about 1995, the so-called ‘computer-to-plate’ (CtP) method has gained a lot of interest. This method, also called ‘direct-to-plate’, bypasses the creation of film because the digital document is transferred directly to a printing plate precursor by means of a so-called plate-setter. A printing plate precursor for CtP is often called a digital plate.

Digital plates can roughly be divided in three categories: (i) silver plates, which work according to the silver salt diffusion transfer mechanism; (ii) photopolymer plates which contain a photopolymerizable composition that hardens upon exposure to light and (iii) thermal plates of which the imaging mechanism is triggered by heat or by light-to-heat conversion. Thermal plates are mainly sensitized for infrared lasers emitting at 830 nm or 1064 nm. Typical photopolymer plates are sensitized for visible light, mainly for exposure by an Ar laser (488 nm) or a FD-YAG laser (532 nm). The wide-scale availability of low cost blue or violet laser diodes, originally developed for data storage by means of DVD, has enabled the production of plate-setters operating at shorter wavelength. More specifically, semiconductor lasers emitting from 350 to 450 nm have been realized using an InGaN material.

Radicals are involved in the hardening reaction of the photopolymerizable composition of photopolymer plates and said hardening reaction is known to be adversely affected by oxygen. To reduce this problem it is known to provide the photosensitive coating with a protective coating, also called oxygen barrier layer, protective overcoat or overcoat layer.

According to DE 26 29 883 A1 the oxygen barrier layer of a presensitized lithographic printing plate should contain a poly(vinyl alcohol), wherein at least 2% of the hydroxy groups of said poly(vinyl alcohol) are esterified by a dicarboxylic acid, to provide an oxygen barrier layer, that can be dissolved in the same solvent as used for the developer and that does not adversely effect the image forming process. The printing plate precursors known from DE 26 29 883 only have a low sensitivity, what is disclosed on p. 17, reading that low exposure (corresponding to high sensitivity) means 3 s when using 4 high pressure mercury vapour lamps of 150 Watts each.

EP 1 148 387 A1 discloses photographic printing plates comprising a photosensitive layer and a protective layer, that have a maximum peak of spectral sensitivity with a wavelength range of from 390 to 430 nm, and wherein the minimum exposure for the photosensitive lithographic printing plate for image formation at a wavelength of 410 nm is at most 100 μJ/cm². Said protective layer is provided on the photosensitive layer as oxygen-shielding layer and preferred examples of protective layers according to EP 1 148 387 A1 contain water-soluble polymers such as poly(vinyl alcohol), poly(vinyl pyrrolidone), poly(ethylene oxide) and cellulose; a mixture of poly(vinyl alcohol) and poly(vinyl pyrrolidone) being particularly preferred.

According to EP 1 280 006 A2a protective layer is provided on the layer of photopolymerizable composition, wherein said protective layer inhibits the penetration of a low molecular compound such as oxygen and can contain water-soluble polymers that have relatively high crystallinity. Preferably poly(vinyl alcohol) with a saponification degree of 71% to 100% is used as a basic component, that may be partially replaced by an ester, ether or acetal, and the photopolymerizable composition comprises a photopolymerization initiation system consisting of a specific sensitizing dye and a titanocene compound.

After imaging (exposing) the photopolymer printing plate precursor, the plate is heated for a short time to high temperatures before the overcoat is washed off and the photolayer is developed. This heating step is hereinafter called pre-heat step. During the pre-heat step typical temperatures, when measured at the back of the plate, from about 90° C. to 120° C. are used for a short time of e.g. about 1 minute. As the conditions of the pre-heat step vary with different types of processors and even for the same processor, a printing plate should exhibit consistent results irrespective to the pre-heat conditions, in particular to the temperature. The range of pre-heat conditions, wherein a printing plate exhibits consistent results is called the pre-heat latitude of said plate.

A good test for the pre-heat latitude is the dot gain, that should be influenced as little as possible by the pre-heat temperature. A printing plate precursor is said to have a good pre-heat latitude if its dot-gain is only little influenced (shows only a small variance) when the pre-heat temperature varies within a range of about 20° C. This means, that the pre-heat latitude can be varied by about 20° C. without visible effect on the resulting print.

The photopolymer printing plate precursors according to the prior art are unsatisfactory, as such plates, when providing suffient speed (sensitivity) to enable a short exposure time with the commercially available low cost and low power blue or violet laser diodes, exhibit an unsatisfactory pre-heat latitude.

### SUMMARY OF THE INVENTION

It is an object of the present invention to provide a high-speed photopolymer printing plate precursor, that has a good pre-heat latitude. This object is realized as defined in claim 1. According to the present invention, the use of an hexaarylbisimidazole as photopolymerization initiator and of a protective overcoat comprising poly(vinyl alcohol) with a specific degree of saponification enables to obtain a high-speed photopolymerizable composition that has a good pre-heat latitude. The printing plate precursor of the present invention is a flexographic or lithographic printing plate precursor, the latter being highly preferred. Also a method of making a lithographic printing plate, wherein said printing plate precursor is exposed with a laser having an emission wavelength in the range from 300 to 450 nm, is an aspect of the present invention. Preferred photopolymer printing plate precursors according to the present invention can be exposed with an energy density, measured on the surface of the plate of 100 μJ/cm² or less. Preferred embodiments of the printing plate precursor, of the method of making a lithographic printing plate and of the use according to the present invention are defined in the dependent claims.

### DETAILED DESCRIPTION OF THE INVENTION

The present invention relates to a photopolymer printing plate precursor comprising in this order a photosensitive coating and a protective coating on a support, wherein said photosensitive coating comprises a composition that is photopolymerizable upon absorption of light, said composition comprising a binder, a polymerizable compound, a sensitizer and a photoinitiator, and wherein said protective coating comprises one or more types of poly(vinyl alcohol), characterized in that said photoinitiator is a hexaaryl-bisimidazole compound and the mean saponification degree of all the polyvinylalcohols which are used in the protective coating is less than 93 mol-%.

A sensitizing dye (sensitizer) preferably used in the present invention, when incorporated in the photopolymerizable composition, has an absorption wavelength ranging from 300 to 450 nm, preferably from 350 to 430 nm and particularly preferred from 360 to 420 nm, and makes the photopolymer printing plate sensitive to light within said wavelength ranges.

The known sensitizing dyes can be used in the composition of the present invention. Suitable classes include dialkylaminobenzene compounds like (Ia) and (Ib)

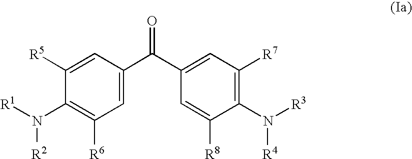

wherein each of R¹ to R⁴, which are independent of one another, is an alkyl group having 1 to 6 carbon atoms (C₁₋₆ alkyl group), and each of R⁵ to R⁸ is a hydrogen atom or a

C₁₋₆ alkyl group, provided that R¹ and R², R³ and R⁴, R¹ and R⁵, R² and R⁶, R³ and R⁷, or R⁴ and R⁸, may be bonded to each other to form a ring;

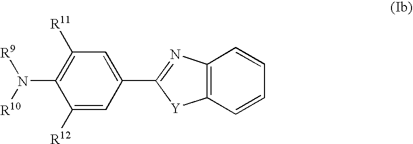

wherein each of R⁹ and R¹⁰, which are independent of each other, is a C₁₋₆ alkyl group, each of R¹¹ and R¹², which are independent of each other, is a hydrogen atom or a C₁₋₆ alkyl group, Y is a sulfur atom, an oxygen atom, dialkylmethylene or —N(R¹³)—, and R¹³ is a hydrogen atom or a C₁₋₆ alkyl group, provided that R⁹ and R¹⁰, R⁹ and R¹¹, or R¹⁰ and R¹², may be bonded to each other to form a ring, as disclosed in EP 1 148 387 A1; compounds according to formula (II)

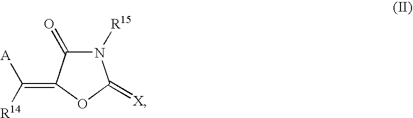

wherein A represents an optionally substituted aromatic ring or heterocyclclic ring, X represents an oxygen atom, a sulfur atom or —N(R¹⁶)—, R¹⁴, R¹⁵ and R¹⁶ each independently represent a hydrogen atom or a monovalent nonmetallic atom group and A and R¹⁴, or R¹⁵ and R³⁶ can be linked together to form an aliphatic or an aromatic ring, as disclosed in EP 1 280 006 A2; 1,3-dihydro-1-oxo-2H-indene compounds as disclosed in EP 1 035 435 A2; the sensitizing dyes disclosed in EP 1 048 982 A1, EP 985 683 A1, EP 1 070 990 A1 and EP 1 091 247 A2; and/or an optical brightening agent.

To achieve the highest possible sensitivity, an optical brightening agent as a sensitizer is preferred. A typical optical brightener, also known as “fluorescent whitening agent”, is a colorless to weakly colored organic compound that is capable of absorbing light having a wavelength in the range from 300 to 450 nm and of emitting the absorbed energy as fluorescent light having a wavelength in the range between 400 and 500 nm. A description of the is physical principle and the chemistry of optical brighteners is given in Ullmann's Encyclopedia of Industrial Chemistry, Sixth Edition, Electronic Release, Wiley-VCH 1998. Basically, suitable optical brightener contain π-electron systems comprising a carbocyclic or a heterocyclic nucleus. Suitable representatives of these compounds are e.g. stilbenes, distyrylbenzenes, distyrylbiphenyls, divinylstilbenes, triazinylaminostilbenes, stilbenzyltriazoles, stilbenzylnaphthotriazoles, bis-triazolstilbenes, benzoxazoles, bisphenylbenzoxazoles, stilbenzylbenzoxazoles, bis-benzoxazoles, furans, benzofurans, bis-benzimidazoles, diphenylpyrazolines, diphenyloxadiazoles, coumarins, naphthalimides, xanthenes, carbostyrils, pyrenes and 1,3,5-triazinyl-derivatives.

More specifically, optical brightening agent having a structure according to one of the following formulae are suitable as sensitizer for use in the composition of the present invention

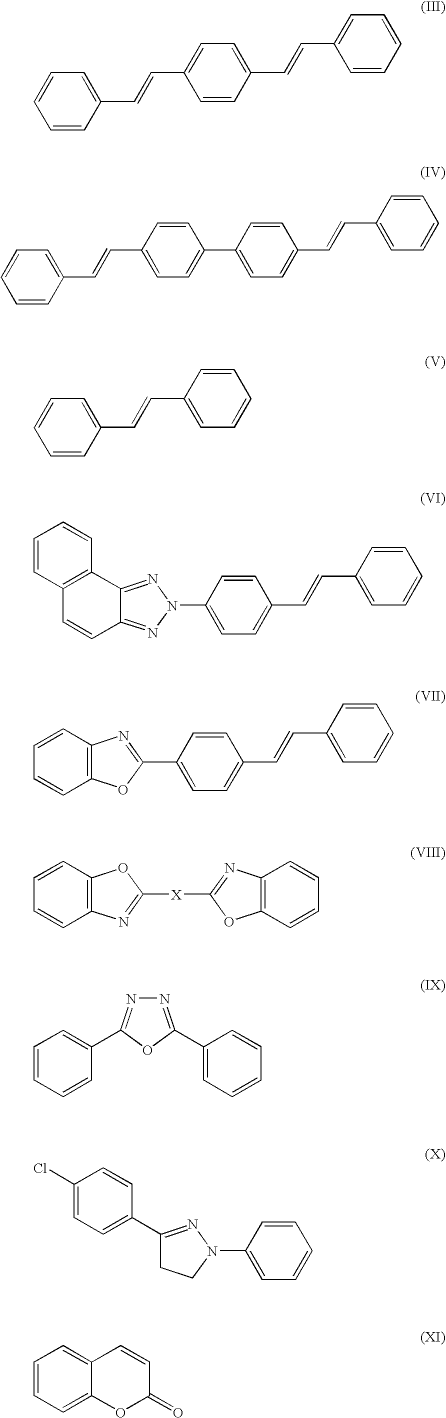

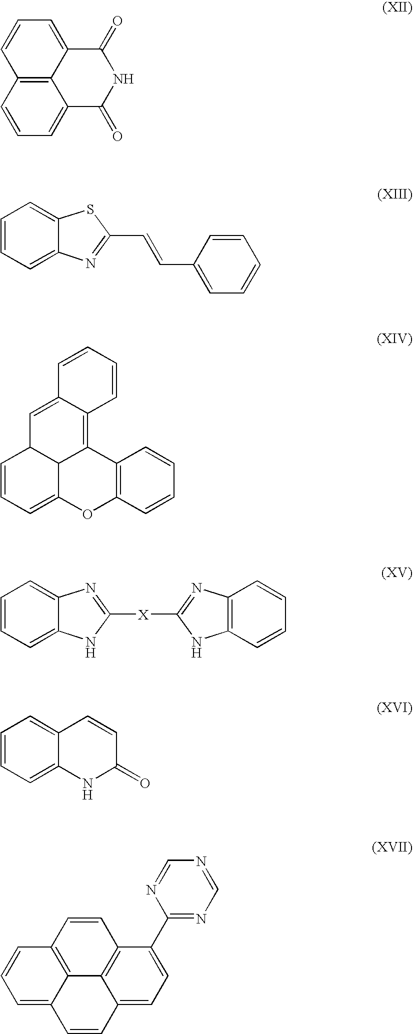

wherein X is one of the following groups, * denoting the position of attachment in the above formulae:

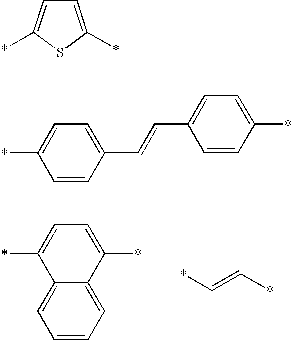

and wherein one or more of the nuclei in each of the above formulae (III) to (XVII) may be independently substituted by one or more groups selected from alkyl, alkoxy, alkylcarbonyl, alkoxycarbonyl, acyloxy, carboxyl, nitrile, amino, hydroxyl, alkylsulfonyl and aminosulfonyl.

Especially suitable optical brighteners are compounds, which are able to be dissolved in organic solvents. The optical brighteners can be used as single compound or as mixture of several materials. The overall amount of these compounds range from 0.1 to 10% by weight, preferably 0.5 to 8% by weight with respect to the total weight of the non-volatile compounds in the photopolymerizable composition.

Highly preferred optical brighteners include compounds of formula (III-A) to (VIII-A):

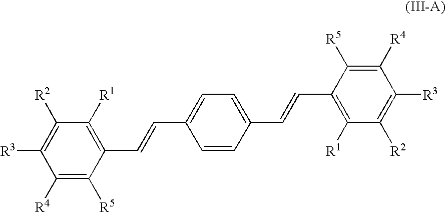

wherein
a) R¹ represents methyl, and R² to R⁵ each represent H,
b) R² to R⁴ represent methoxy, and R¹ and R⁵ represent H,
c) R³ represents CN, and R² to R⁵ each represent H or
d) R³ represents CN, and R¹, R², R⁴ and R⁵ each represent H;

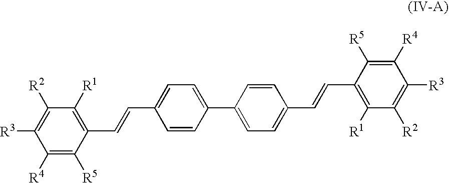

wherein R¹ to R⁴ each represent H, and R⁵ represents methoxy;

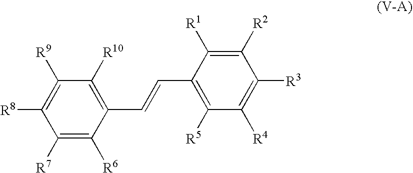

wherein
a) R¹ to R¹⁰ each represent H,
b) R¹, R² and R⁴ to R¹⁰ each represent H, and R³ represents methoxy or
c) R¹, R², R⁴ to R⁷, R⁹ and R¹⁰ each represent H, and R³ and R⁸ each represent methoxy;

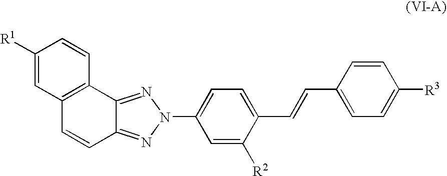

wherein
a) R¹ and R³ represent H, and R² represents phenylsulfonic acid or phenylsulfonic acid salts or
b) R¹ represents H, R² represents CN and R³ represents Cl;

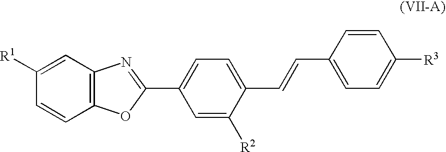

wherein
a) R¹ represents t-butyl, R² represents H and R³ represents phenyl,
b) R¹ represents methyl, R² represents H, and R³ represents carboxymethyl or
c) R¹ represents H, R² represents H, and R³ represents 2-(4-methyl-oxa-3,3-diazole);

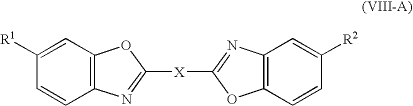

wherein
a) X represents 4,4′-stilbenediyl, and R¹ and R² each represent H,
b) X represents 2,5-thiophenediyl, and R¹ and R² each represent t-butyl,
c) X represents 1,4-naphthalenediyl, and R¹ and R² each represent H or
d) X represents 1,1-ethenediyl, and R¹ and R² each represent methyl;

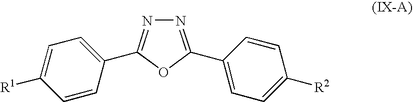

wherein R¹ and R² each represent diethylamino;

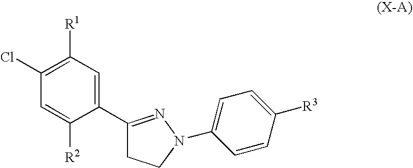

wherein
a) R¹ and R² each represent H, and R³ represents SO₂NH₂,
b) R¹ and R² each represent H, and

R³ represents SO₂CH₂CH₂CH₂CH₂N(CH₃)₂,

c) R¹ and R² each represent H, and

R³ represents SO₂CH₂CH₂OCH(CH₃)CH₂N(CH₃)₂,

d) R¹ and R² each represent H, and R³ represents SO₂CH₃ or
e) R¹ and R² each represent H, and R³ represents SO₂CH₂CH₂OH;

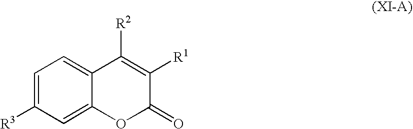

wherein
a) R¹ represents H, R² represents Me, and R³ represents diethylamino,
b) R¹ represents phenyl, R² represents H, and

R³ represents 2-N-naphthatriazolyl,

c) R¹ represents H, R² represents methyl, and R³ represents OH,
d) R¹ represents phenyl, R² represents H,

and R³ represents NH-(4,6-dichloro)-(1,3,5)-triazine or

e) R¹ represents Ph, R² represents H, and

R³ represents 1-(3-methylpyrazolinyl);

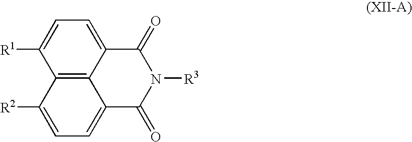

wherein
a) R¹ represents H, R² represents methoxy, and R³ represents methyl; or
b) R¹ and R² each represent OEt, and R³ represents methyl;

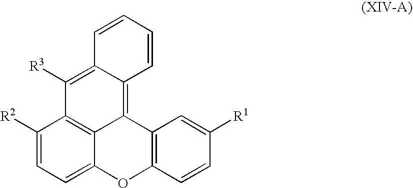

wherein
a) R¹ and R² each represent methyl, and R³ represents H or
b) R¹ and R² each represent methyl, and R³ represents carboxymethyl;

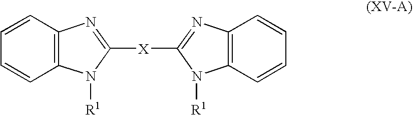

wherein
a) X represents 1,2-ethenediyl, and R¹ represents Me or
b) X represents 4,4′-stilbenediyl, and R¹ represents methyl;

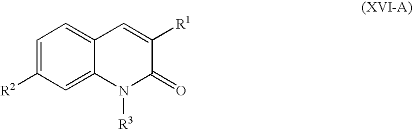

wherein R¹ represents Ph, R² represents diethylamino, and R³ represents ethyl; and

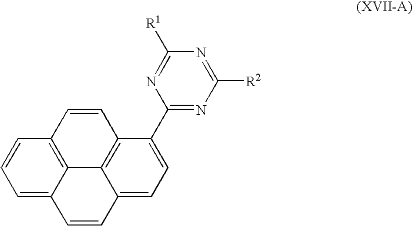

wherein R³ and R² each represent methoxy.

From those sensitizers, the following compounds of formulae (IIIa) and/or (IVa) are particularly preferred:

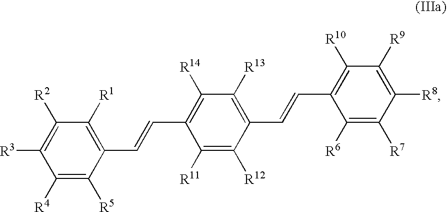

wherein
R¹ to R¹⁴ in dependently represent a hydrogen atom, an alkyl group, an alkoxy group, a cyano group or a halogen atom,
and at least one of R¹ to R¹⁰ represents an alkoxy group having more than 1 carbon atom;

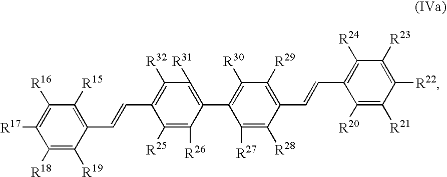

wherein
R¹⁵ to R³² independently represent a hydrogen atom, an alkyl group, an alkoxy group, a cyano group or a halogen atom,
and at least one of R¹⁵ to R²⁴ represents an alkoxy group having more than 1 carbon atom. The alkyl and alkoxy groups of the present invention can be optionally substituted and their substituent can be selected to adjust the solubility of the sensitizer and may be, for example, halogen, ester, ether, thioether or hydroxy. The alkyl or alkoxy groups may be straight chain or cyclic, but a branched chain is preferred for the sensitizers of formulae (IIIa) and (IVa).

Particular advantages are achieved with sensitisers of formula (IIIa), wherein R¹, R⁵, R⁶, R¹⁰, R¹¹, R¹², R¹³ and R¹⁴ independently represent a hydrogen atom, a fluorine atom or a chlorine atom, in particular R¹, R⁵, R⁶, and R¹⁰ being a hydrogen atom; R² to R⁴, R⁷ to R⁹, independently are alkoxy groups; and at least two of the alkoxy groups are branched and have from 3 to 15 carbon atoms. Especially preferred for the present invention are sensitizers of formulae (IIIa) as disclosed above, wherein R², R⁴, R⁷, R⁹ independently represent a methoxy group and R³ and R⁸ independently are branched alkoxy groups having 3 to 15 carbon atoms.

Particular advantages are also achieved with sensitisers of formula (IVa), wherein R¹⁵, R¹⁹, R²⁰, R²⁴, R²⁵ to R³², independently represent a hydrogen atom, a fluorine atom or a chlorine atom, in particular R¹⁵, R¹⁹, R²⁰, R²⁴ being a hydrogen atom; R¹⁶ to R¹⁸, R²¹ to R²³, independently are alkoxy groups; and at least two of the alkoxy groups are branched and have from 3 to 15 carbon atoms. Especially preferred for the present invention are sensitizers of formulae (IVa) as disclosed above, wherein R¹⁶, R¹⁸, R²¹, R²³ independently represent a methoxy group and R¹⁷ and R²² independently are branched alkoxy groups having 3 to 15 carbon atoms.

The following structures are examples of preferred sensitizers of the present invention and their solubility S is given in brackets as g sensitizer/kg methyl ethyl ketone measured at 20° C.

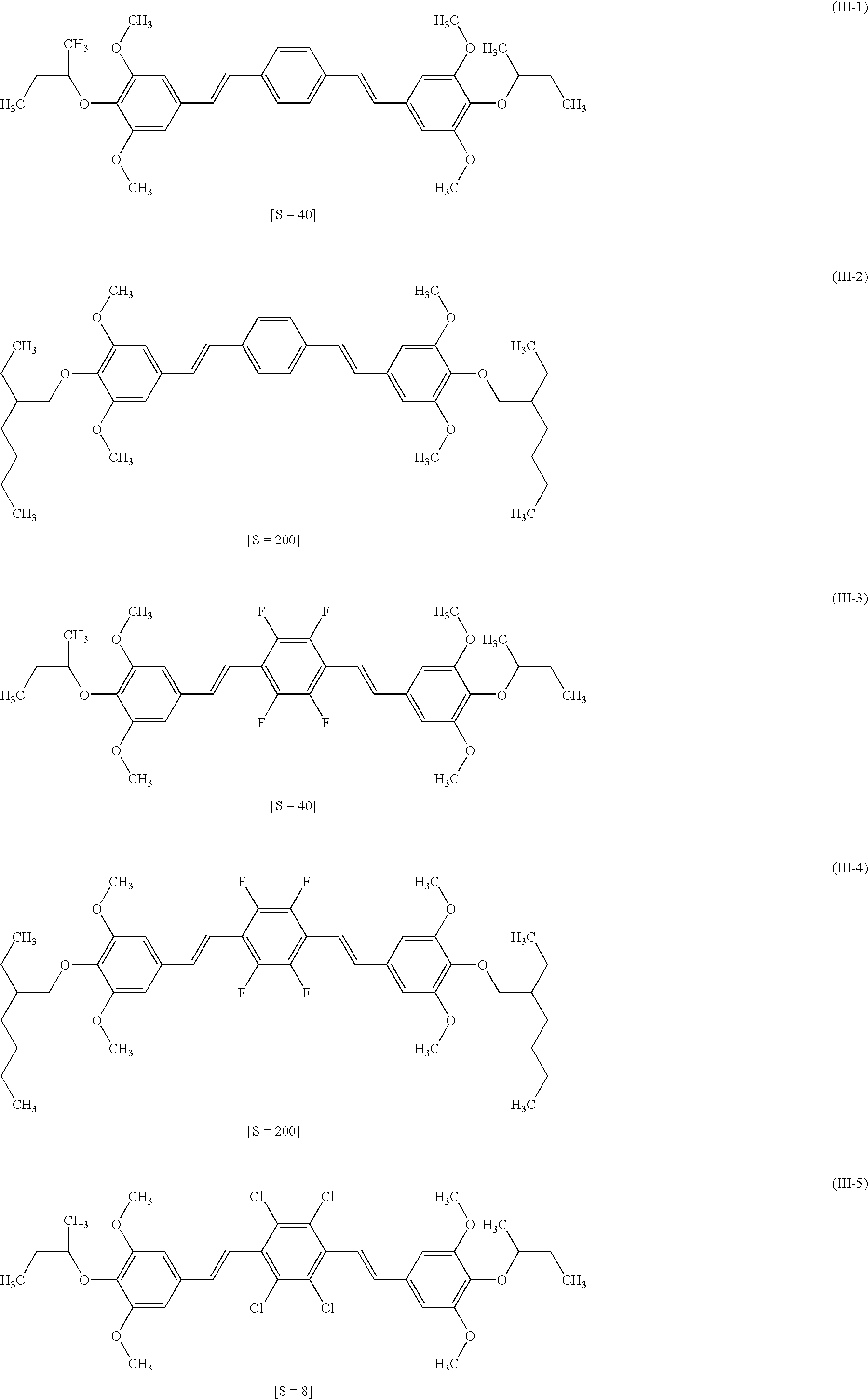

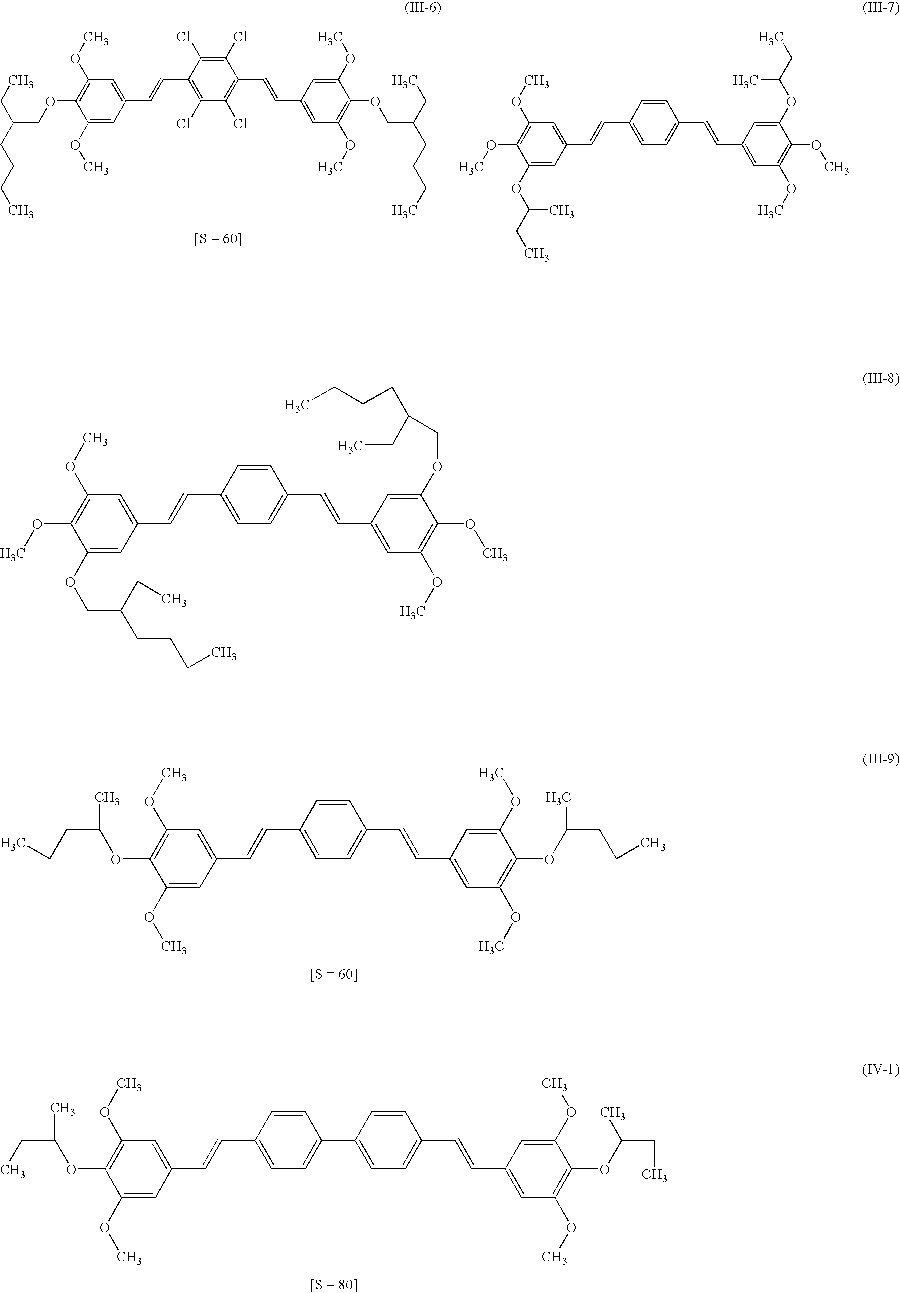

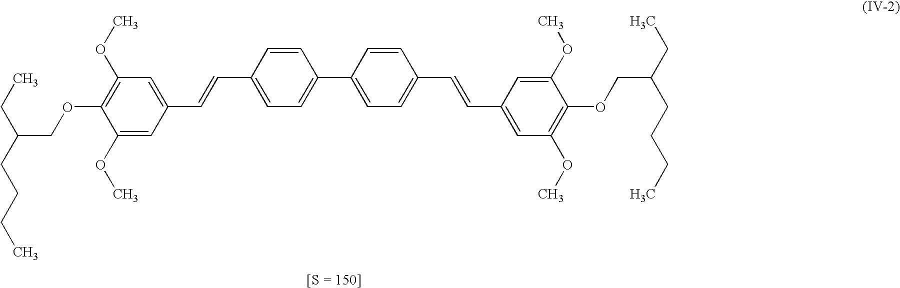

Most sensitizers useful for the present invention can be synthesised by known methods and the synthesis of the highly preferred sensitizers of formulae (IIIa) and (IVa) can be done in analogy to the synthesis of sensitizer (III-1) as disclosed in the following.

### Synthesis of Intermediate (C-3)

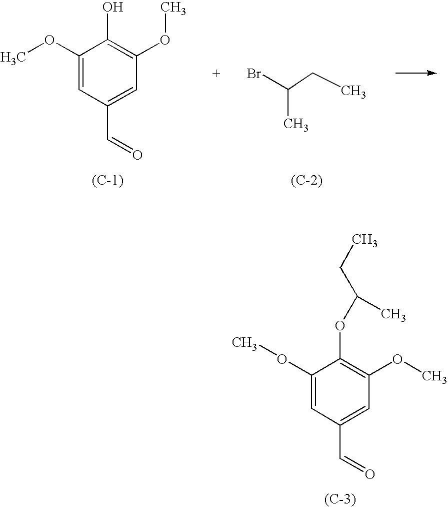

To a mixture of 8.365 kg (45.0 mol) syringaldehyde (C-1) and 1.494 kg (9.0 mol) potassium iodide is added 20.25 L sulfolane at room temperature. After heating up this mixture to 30° C. under nitrogen, 3.12 kg (47.25 mol) of KOH in water and 2.80 kg (20.25 mol) K₂CO₃ are added. After warming the reaction mixture to 75° C., 12.78 kg (90.0 mol) 2-bromo butane (C-2) is added over a period of 30 minutes. Heating at 75° C. is continued for 24 hours, followed by cooling to 25° C. Then 25 L Water is added and the reaction product is extracted with 18 L methyl t-butyl ether (MTBE). The organic phase is consecutively a) two times washed with 6.0 L of a 7.5 wt. % K₂CO₃ solution in water respectively, b) two times washed with 13.5 L of pure water respectively and finally, c) two times washed with 4.5 kg of a 20 wt. % NaCl solution in water respectively. The solvent (MTBE) is removed by distillation under reduced pressure of 50 mBar at 75° C. and thereby are obtained 7.845 kg (theoretical yield of 75%) of the crude intermediate (C-3) as a yellow oil, that is used in the synthesis of (III-1) without further purification.

### Synthesis of Sensitizer (III-1)

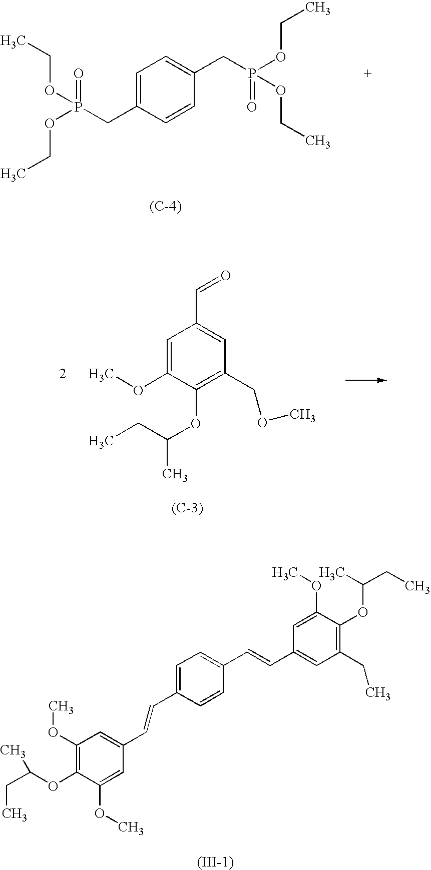

To a mixture of 9.63 kg (25.46 mol) p-xylylene-bis-phosphonate (C-4) and 12.13 kg (50.92 mol) of the crude intermediate (C-3) in 20 L THF, 4.70 kg (71.3 mol) of KOH is added at room temperature. After heating the stirred reaction mixture at reflux for 3.5 hours, the reaction product is precipitated by adding a mixture of 25.2 kg methanol and 9.9 kg water, followed by further cooling to 20° C. The crystalline product (III-1) is filtered off, washed with several portions of methanol/water on the filter and dried at 50° C. The yield is 9.05 kg (theoretical yield of 67%) of (III-1) having a melting point of 154° C.

A suitable synthesis for the p-xylylene-bis-phosphonate (C-4) is known from the literature, e.g. from B. P. Lugovkin and B. A. Arbuzov, Doklady Akademii Nauk SSSR (1948), 59, pages 1301 to 1304.

The photopolymerizable composition according to the present invention comprises a hexaarylbisimadole (HABI, dimer of triaryl-imidazole) compound as a photopolymerization initiator.

A procedure for the preparation of hexaarylbisimidazoles is described in DE 1470 154 and their use in photopolymerizable compositions is documented in EP 24 629, EP 107 792, U.S. Pat. No. 4,410,621, EP 215 453 and DE 3 211 312. Preferred derivatives are e.g. 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)-bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole and 2,2′-bis(2,6-difluorophenyl)-4,5,4′,5′-tetraphenylbisimidazole. The amount of the HABI photoinitiator typically ranges from 0.01 to 30% by weight, preferably from 0.5 to 20% by weight, relative to the total weight of the non volatile components of the photopolymerizable composition.

The best results, in particular the highest sensitivity, can be obtained by the combination of an optical brightener as sensitizer and a hexaarylbisimidazole as photoinitiator, sensitizers of formulae (III) and (IV) being particularly preferred.

Hexaarylbisimidazole compounds can be used as photoinitiators either alone or in combination with further photoinitiators. The known photopolymerization initiators can be used in the composition of the present invention in combination with hexarylbisimidazole compounds. Suitable classes include aromatic ketones, aromatic onium salts, organic peroxides, thio compounds, ketooxime ester compounds, borate compounds, azinium compounds, metallocene compounds, active ester compounds and compounds having a carbon-halogen bond. Many specific examples of such photoinitiators can be found in EP-A 1091247.

Preferably hexaarylbisimidazole compounds are used alone or in combination with aromatic ketones, aromatic onium salts, organic peroxides, thio compounds, ketoxime ester compounds, borate compounds, azinium compounds, active ester compounds or compounds having a carbon halogen bond.

In a preferred embodiment of the present invention the hexaarylbisimidazole compounds make more than 50 mol-%, preferably at least 80 mol-% and particularly preferred at least 90 mol-% of all the photoinitiators used in the photopolymerizable composition of the present invention.

The binder can be selected from a wide series of organic polymers. Compositions of different binders can also be used. Useful binders include for example chlorinated polyalkylenes in particular chlorinated polyethylene and chlorinated polypropylene; poly(methacrylic acid) alkyl esters or alkenyl esters in particular poly(methyl (meth)acrylate), poly(ethyl (meth)acrylate), poly(butyl (meth)acrylate), poly(isobutyl (meth)acrylate), poly(hexyl (meth)acrylate), poly((2-ethylhexyl) (meth)acrylate) and poly(alkyl (meth)acrylate); copolymers of (meth)acrylic acid alkyl esters or alkenyl esters with other copolymerizable monomers, in particular with (meth)acrylonitrile, vinyl chloride, vinylidene chloride, styrene and/or butadiene; poly(vinyl chloride) (PVC); vinylchloride/(meth)acrylonitrile copolymers; poly(vinylidene chloride) (PVDC); vinylidene chloride/(meth)acrylonitrile copolymers; poly(vinyl acetate); poly(vinyl alcohol); poly (meth)acrylonitrile; (meth)acrylonitrile/styrene copolymers; (meth)acrylamide/alkyl (meth)acrylate copolymers; (meth)acrylonitrile/butadiene/styrene (ABS) terpolymers; polystyrene; poly(α-methylstyrene); polyamides; polyurethanes; polyesters; cellulose or cellulose compounds like methyl cellulose, ethyl cellulose, acetyl cellulose, hydroxy-(C₁₋₄-alkyl)cellulose, carboxymethyl cellulose; poly(vinyl formal) and poly(vinyl butyral). Particularly suitable are binders that are insoluble in water, but on the other hand are soluble or at least swellable in aqueous-alkaline solutions. Further effective binders are polymers that are soluble in common organic coating solvents.

Particular suitable for the purpose of the present invention are binders containing carboxyl groups, in particular polymers or copolymers containing monomeric units of α,β-unsaturated carboxylic acids and/or monomeric units of α,β-unsaturated dicarboxylic acids, preferably acrylic acid, methacrylic acid, crotonic acid, vinylacetic acid, maleic acid or itaconic acid. By the term “copolymers” are to be understood in the context of the present invention polymers containing units of at least 2 different monomers, thus also terpolymers and higher mixed polymers. Particular useful examples of copolymers are those containing units of (meth)acrylic acid and units of alkyl (meth)acrylates, allyl (meth)acrylates and/or (meth)acrylonitrile as well as copolymers containing units of crotonic acid and units of alkyl (meth)acrylates and/or (meth)acrylonitrile and vinylacetic acid/alkyl (meth)acrylate copolymers. Also suitable are copolymers containing units of maleic anhydride or maleic acid monoalkyl esters. Among those are, for example, copolymers containing units of maleic anhydride and styrene, unsaturated ethers or esters or unsaturated aliphatic hydrocarbons and the esterification products obtained from such copolymers. Further suitable binders are products obtainable from the conversion of hydroxyl-containing polymers with intramolecular dicarboxylic anhydrides. Further useful binders are polymers in which groups with acid hydrogen atoms are present, some or all of which are converted with activated isocyanates. Examples of these polymers are products obtained by conversion of hydroxyl-containing polymers with aliphatic or aromatic sulfonyl isocyanates or phosphinic acid isocyanates. Also suitable are polymers with aliphatic or aromatic hydroxyl groups, for example copolymers containing units of hydroxyalkyl (meth)acrylates, allyl alcohol, hydroxystyrene or vinyl alcohol, as well as epoxy resins, provided they carry a sufficient number of free OH groups.

The organic polymers used as binders have a typical mean molecular weight M_{w} between 600 and 200 000, preferably between 1 000 and 100 000. Preference is further given to polymers having an acid number between 10 to 250, preferably 20 to 200, or a hydroxyl number between 50 and 750, preferably between 100 and 500. The amount of binder(s) generally ranges from 10 to 90% by weight, preferably 20 to 80% by weight, relative to the total weight of the non-volatile components of the composition.

The polymerizable compound can be selected from a wide series of photo-oxidizable compounds. Suitable compounds contain primary, secondary and in particular tertiary amino groups. Radically polymerizable compounds containing at least one urethane and/or urea group and/or a tertiary amino group are particularly preferred. By the term “urea group” has to be understood in the context of the present invention a group of the formula >N—CO—N<, wherein the valences on the nitrogen atoms are saturated by hydrogen atoms and hydrocarbon radicals (with the proviso that not more than one valence on either of the two nitrogen atoms is saturated by one hydrogen atom). However, it is also possible for one valence on one nitrogen atom to be bonded to a carbamoyl (—CO—NH—) group, producing a biuret structure.

Also suitable are compounds containing a photo-oxidizable amino, urea or thio group, which may be also be a constituent of a heterocyclic ring. Compounds containing photo-oxidizable enol groups can also be used. Specific examples of photo-oxidizable groups are triethanolamino, triphenylamino, thiourea, imidazole, oxazole, thiazole, acetylacetonyl, N-phenylglycine and ascorbic acid groups. Particularly suitable compounds are monomers containing photo-oxidizable groups corresponding to the following formula (XVIII):

R₍ₘ₋ₙ₎Q [(—CH₂—CR¹R²—O)ₐ—CO—NH—(X¹—NH—CO—O)_{b}—X²—(O—CO—CR³═CH₂)_{c}]ₙ (XVIII

wherein
R represents an alkyl group having 2 to 8 carbon atoms ((C₂-C₈) alkyl group), a (C₂-C₈) hydroxyalkyl group or a (C₆-C₁₄) aryl group,
Q represents

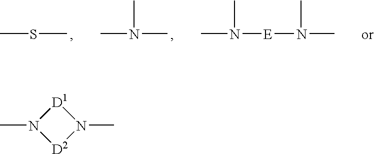

wherein
E represents a divalent saturated hydrocarbon group of 2 to 12 carbon atoms, a divalent 5- to 7-membered, saturated iso- or heterocyclic group, which may contain up to 2 nitrogen, oxygen and/or sulfur atoms in the ring, a divalent aromatic mono- or bicyclic isocyclic group of 6 to 12 carbon atoms or a divalent 5- or 6-membered aromatic heterocyclic group; and
D¹ and D² independently represent a saturated hydrocarbon group of 1 to 5 carbon atoms,
R¹ and R² independently represent a hydrogen atom, an alkyl or alkoxyalkyl group,
R³ represents a hydrogen atom, a methyl or ethyl group,
X¹ represents a straight-chained or branched saturated hydrocarbon group of 1 to 12 carbon atoms,
X² represents a (c+1)-valent hydrocarbon group in which up to 5 methylene groups may have been replaced by oxygen atoms,
a is an integer from 0 to 4,
b is 0 or 1,
c is an integer from 1 to 3,
m is an integer from 2 to 4 and
n is an integer from 1 to m.

Compounds of this nature and processes for their preparation are described in EP 287 818. If a compound of general formula (XVIII) contains several radicals R or several radicals according to the structure indicated between square brackets, i.e. if (n−m)>1 and n>1, these radicals can be identical or different from one another. Compounds according to formula (XVIII) wherein n=m are particularly preferred. In this case, all radicals contain polymerizable groups. Preferably, the index a is 1; if several radicals are present, a cannot be 0 in more than one radical. If R is an alkyl or hydroxyalkyl group, R generally contains 2 to 6, particularly 2 to 4 carbon atoms. Aryl radicals R are in general mononuclear or binuclear, preferably however mononuclear, and may be substituted with (C₁-C₅) alkyl or (C₁-C₅) alkoxy groups. If R¹ and R² are alkyl or alkoxy groups, they preferably contain 1 to 5 carbon atoms. R³ is preferably a hydrogen atom or a methyl group. X¹ is preferably a straight-chained or branched aliphatic and/or cycloaliphatic radical of preferably 4 to 10 carbon atoms. In a preferred embodiment, X² contains 2 to 15 carbon atoms and is in particular a saturated, straight-chained or branched aliphatic and/or cycloaliphatic radical containing this amount of carbon atoms. Up to 5 methylene groups in these radicals may have been replaced by oxygen atoms; in the case of X² being composed of pure carbon chains, the radical generally has 2 to 12 carbon atoms, preferably 2 to 6 carbon atoms. X² can also be a cycloaliphatic group of 5 to 10 carbon atoms, in particular a cyclohexane diyl group. The saturated heterocyclic ring formed by D¹, D² and both nitrogen atoms generally has 5 to 10 ring members in particular 6 ring members. In the latter case the heterocyclic ring is preferably a piperazine and the radical derived therefrom a piperazine-1,4-diyl radical. In a preferred embodiment, radical E is an alkane diyl group which normally contains about 2 to 6 carbon atoms. Preferably the divalent 5- to 7-membered, saturated, isocyclic group E is a cyclohexane diyl group, in particular a cyclohexane-1,4-diyl group. The divalent, isocyclic, aromatic group E is preferably an ortho-, meta- or para-phenylene group. The divalent 5- or 6-membered aromatic heterocyclic group E, finally, contains preferably nitrogen and/or sulphur atoms in the heterocyclic ring. c is preferably 1, i.e. each radical in the square bracket generally contains only one polymerizable group, in particular only one (meth)acryloyloxy-group.

The compounds of formula (XVIII) wherein b=1, which accordingly contain two urethane groups in each of the radicals indicated in the square brackets, can be produced in a known way by conversion of acrylic esters or alkacrylic esters which contain free hydroxyl groups with equimolar amounts of diisocyanates. Excess isocyanate groups are then, for example, reacted with tris(hydroxyalkyl)amines, N,N′-bis(hydroxyalkyl)piperazines or N,N,N′,N′-tetrakis(hydroxyalkyl)alkylenediamines, in each of which individual hydroxyalkyl groups may have been replaced by alkyl or aryl groups R. If a=0, the result is a urea grouping. Examples of the hydroxyalkylamine starting materials are diethanolamine, triethanolamine, tris(2-hydroxypropyl)amine, tris(2-hydroxybutyl)amine and alkyl-bis-hydroxyalkylamines. Examples of suitable diisocyanates are hexamethylene diisocyanate, 2,2,4-trimethylhexamethylene diisocyanate, 1,4-cyclohexylene diisocyanate (=1,4-diisocyanatocyclohexane) and 1,1,3-trimethyl-3-isocyanatomethyl-5-isocyanatocyclohexane. The hydroxy-containing esters used are preferably hydroxyethyl (meth)acrylate, hydroxypropyl (meth)acrylate and hydroxyisopropyl (meth)acrylate.

The polymerizable compounds of formula (XVIII) wherein b=0 are prepared converting the above-described hydroxyalkylamino compounds with isocyanate-containing acrylic or alkacrylic esters. A preferred isocyanate-containing ester is isocyanoto-ethyl (meth)acrylate.

Further polymerizable compounds comprising photooxidisable groups suitable for the purpose of the invention are compounds according to the following formula (XIX):

R₍ₘ₋ₙ₎Q[(—CH₂—CR¹R²—O)ₐ—(CH₂—CH[CH₂—O—CO—CR³═CH₂]—O)_{b}—H]ₙ (XIX)

wherein a′ and b′ independently represent integers from 1 to 4 and Q, R¹, R², R³, n and m have the same meaning as above and Q can also be a group of the formula >N-E′-N< wherein the radical E′ corresponds to the following formula (XX):

—CH₂—CH(OH)—CH₂—[O—(p)C₆H₄—C(CH₃)₂-(p)C₆H₄—CH₂—CH(OH)—CH₂—]_{c} (XX)

wherein c has the same meaning as in formula (I) and (p)C₆H₄ represents para-phenylene.

The compounds of formula (XIX) are prepared analogously to those of formula (XVIII), except that the conversion products of hydroxyalkyl acrylates or alkacrylates and diisocyanates are replaced by the corresponding acrylic and alkacrylic glycide esters. Compounds of formula (XX) and processes to their preparation are disclosed in EP 316 706.

Further useful polymerizable compounds containing photooxidisable groups are acrylic and alkacrylic esters of the following formula (XXI):

Q′[(—X^{1′}—CH₂—O)ₐ—CO—NH(—X¹—NH—CO—O)_{b}—X²—O—CO—CR³═CH₂]ₙ (XXI)

wherein
Q′ represents

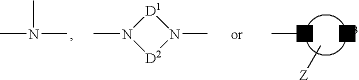

wherein D¹ and D² independently represent a saturated hydrocarbon group of 1 to 5 carbon atoms and D³ represents a saturated hydrocarbon group of 4 to 8 carbon atoms, which together with the nitrogen atom forms a 5- or 6-membered heterocyclic ring;
X¹ represents —CᵢH₂₁— or

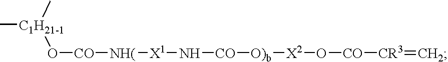

Z represents a hydrogen atom or a radical of the following formula:

—CₖH₂ₖ—O—CO—NH(—X¹—NH—CO—O)_{b}—X²—O—CO—CR³═CH₂;

i,k independently represent integers from 1 to 12;
n′ represents an integer from 1 to 3; and
a is 0 or 1; provided that a is 0 in at least one of the radicals bonded to Q;
X¹, R³, a and b have the same meaning as given in the above formula (VIII); and
X² represents a divalent hydrocarbon group in which up to 5 methylene groups may be replaced by oxygen atoms.

In formula (XXI) index a is preferably 0 or 1 and i preferably represents a number between 2 and 10. Preferred radicals Q are piperazine-1,4-diyl (D¹=D²=CH₂—CR₂), piperidine-1-yl (D³=(CH₂)₅, Z=H) and 2-(2-hydroxyethyl)-piperidine-1-yl (D³=(CH₂)₅, Z=CH₂CH₂OH).

Of the compounds of formula (XXI), those which apart from a urea group contain at least one urethane group are preferred. Here again, by the term “urea group” has to be understood the group of formula >N—CO—N<already mentioned above. Compounds of formula (XXI) and processes for their preparation are disclosed in EP 355 387.

Also suitable polymerizable compounds are reaction products of mono- or diisocyanates with multifunctional alcohols, in which the hydroxy groups are partly or completely esterified with (meth)acrylic acid. Preferred compounds are materials, which are synthesized by the reaction of hydroxyalkyl-(meth)acrylates with diisocyanates. Such compounds are basically known and for instance described in DE 28 22 190 and DE 20 64 079.

The amount of polymerizable compound comprising photooxidisable groups generally ranges from 5 to 75% by weight, preferably from 10 to 65% by weight, relative to the total weight of the non volatile compounds of the photopolymerizable composition.

Moreover, the composition can contain polyfunctional (meth)acrylate or alkyl(meth)acrylate compounds as crosslinking agents. Such compounds contain more than 2, preferably between 3 and 6 (meth)acrylate and/or alkyl(meth)acrylate groups and include in particular (meth)acrylates of saturated aliphatic or alicyclic trivalent or polyvalent alcohols such as trimethylol ethane, trimethylol propane, pentaerythritol or dipentaerythritol.

The total amount of polymerizable compounds generally ranges from about 10 to 90% by weight, preferably from about 20 to 80% by weight, relative to the total weight of the non volatile components of the photopolymerizable composition of the present invention.

The following specific example is also a suitable polymerizable compound:

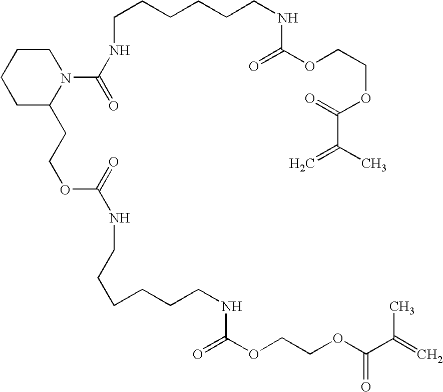

In order to achieve a high sensitivity, it is advantageous to add a radical chain transfer agent as described in EP 107 792 to the photopolymerizable composition of the present invention. The preferred chain transfer agents are sulfur containing compounds, especially thiols like e.g. 2-mercaptobenzothiazole, 2-mercaptobenzoxazole or 2-mercapto-benzimidazole. The amount of chain transfer agent generally ranges from 0.01 to 10% by weight, preferably from 0.1 to 2% by weight, relative to the total weight of the non volatile components of the photopolymerizable composition.

Optionally pigments, e.g. predispersed phthalocyanine pigments, can be added to the composition of the present invention for dyeing the composition and the layers produced therewith. Their amount generally ranges from about 1 to 15% by weight, preferably from about 2 to 7% by weight related to the total weight of the non volatile components of the composition. Particularly suitable predispersed phthalocyanine pigments are disclosed in DE 199 15 717 and DE 199 33 139. Preference is given to metal-free phthalocyanine pigments.

In order to adjust the photopolymerizable composition according to the present invention to specific needs, thermal inhibitors or stabilizers for preventing thermal polymerization may be added. Furthermore additional hydrogen donors, dyes, colored or colorless pigments, color formers, indicators and plasticisers may be present. These additives are conveniently selected so that they absorb as little as possible in the actinic range of the imagewise applied radiation.

The photopolymerizable composition according to the present invention is applied to the support by processes which are known per se to the person skilled in the art. In general, the components of the photopolymerizable composition are dissolved or dispersed in an organic solvent or solvent mixture, the solution or dispersion is applied to the intended support by pouring on, spraying on, emersion, roll application or in a similar and the solvents are removed during the subsequent drying.

The known supports can be used for the photopolymer printing plate of the present invention, like e.g. foils, tapes or plates made of metal or plastics and in the case of screen-printing also of Perlon gauze. Preferred metals are aluminium, aluminium alloys, steel and zinc, aluminium and aluminium alloys being particularly preferred. Preferred plastics are polyester and cellulose acetates, polyethyleneterephthalate (PET) being particularly preferred.

In most cases it is preferred, to treat the surface of the support mechanically and/or chemically and/or electrochemically to optimally adjust the adherence between the support and the photosensitive coating and/or to reduce the reflection of the imagewise exposed radiation on the surface of the support (antihalation).

The most preferred support to be used for the present invention is made of aluminium or an aluminium alloy, its surface is electrochemically roughened, thereafter anodized and optionally treated with a hydrophilizing agent like e.g. poly(vinylphosphonic acid).

The protective overcoat according to the present invention comprises at least one type of poly(vinyl alcohol), wherein the mean degree of saponification is less than 93 mol-%.

The degree of saponification is related to the production of poly(vinyl alcohols). As the monomer of poly(vinyl alcohol), vinyl alcohol, is nonexistent, only indirect methods are available for the production of poly(vinyl alcohol). The most important manufacturing process for poly(vinyl alcohol) is the polymerization of vinyl esters or ethers, with subsequent saponification or transesterification. The preferred starting material for the poly (vinyl alcohol) of the present invention is a vinyl alcohol esterified by a mono carboxylic acid and in particular vinyl acetate, but derivatives of vinyl acetate, vinyl esters of di carboxylic acids, vinyl ethers and the like can also be used. The degree of saponification as defined for the present invention is the molar degree of hydrolysis irrespective of the process used for the hydrolysis. Pure poly (vinyl alcohol) has e.g. a degree of saponification of 100 mol-%, but commercial products often have a degree of saponification of 98 mol-%. The poly(vinyl alcohols) as used for the present invention contain mainly 1,3-diol units, but may also contain small amounts of 1,2-diol units. In the partially saponified poly(vinyl alcohols) the ester or the ether group can be distributed statistically or blockwise. Preferred partially saponified poly(vinyl alcohols) of the present invention have a viscosity of a 4% aqueous solution at 20° C. of 4 to 60 mPa·s, preferably of 4 to 20 mPa·s and in particular of 4 to 10 mPa·s.

Poly(vinyl alcohols) preferred for the present invention are commercially available e.g. under the tradename Mowiol. Those products are characterised by two appended numbers, meaning the viscosity and the degree of saponification. For example, Mowiol 8-88 or Mowiol 8/88 mean a poly(vinyl alcohol) having as 4% aqueous solution at 20° C. a viscosity of ca 8 mPa·s and a degree of saponification of 88 mol-%. Although the use of only one type of poly(vinyl alcohol) is sufficient to achieve the object of the present invention, it is preferred to use a mixture of two or more compounds, because this allows a more accurate adjustment of the pre-heat latitude and a better optimization of further properties of the printing plate precursor. Preferably poly(vinyl alcohols) differing in viscosity as defined above and/or in saponification degree are combined. Particularly preferred are mixture of poly(vinyl alcohols) that differ in viscosity of their 4% aqueous solutions at 20° C. for at least 2 mPa·s or that differ in saponification degree for at least 5 mol-%. Most preferred are mixtures comprising at least 3 types of poly(vinyl alcohols), wherein at least two compounds differ in viscosity as defined above for at least 2 mPa·s and at least two compounds differ in saponification degree for at least 5 mol-%.

According to the present invention the overall mean saponification degree of all poly(vinyl alcohols) used in the protective layer has to be less than 93 mol-%. Higher saponification degrees lead to an unacceptable material with no pre-heat latitude. In a preferred embodiment of the present invention said overall mean saponification degree ranges from 71 mol-% to less than 93 mol-% and in particular from 80 mol-% to 92,9 mol-%.

As long as said mean overall saponification limit of 93 mol-% is not reached, one of the poly(vinyl alcohols) used in a mixture can have a mean saponification degree of more than 93 mol-% and even up to 100 mol-%.

The overall mean saponification degree of the poly(vinyl alcohols) used in the protective overcoat of a printing plate precursor can be determined experimentally via ¹³C-NMR. To measure the ¹³C-NMR spectra, approximately 200 mg of the protective overcoat are dissolved in 1.0 ml DMSO and from this solution a 75 MHz ¹³C-NMR spectrum is taken, whose resonances can easily be interpreted and allow to calculate the degree of saponification. Such values are listed in the Examples, in Table 3, as experimental values. A good correlation is obtained between said experimental values and the values known from the product specification of the poly(vinyl alcohols). The latter values are hereinafter called theoretical values of the mean saponification degree and can easily be calculated, when mixture of poly(vinyl alcohols) are used.

Preferably the poly(vinyl alcohol) of the present invention is used in 50 to 99.9 weight percent (wt. %) relative to the total weight of the non-volatile compounds of the protective overcoat. Additionally other water soluble polymers can be added to the layer such as poly(vinyl pyrrolidone), poly(ethylene oxide), gelatin, gum arabic, oxygen binding polymers with aliphatic amine groups known from EP 352 630 B1, methyl vinylether/maleic anhydride copolymers, poly(carboxylic acids), copolymers of ethylene oxide and poly(vinyl alcohol), carbon hydrates, hydroxy ethyl cellulose, acidic cellulose, cellulose, poly(arylic acid) and mixtures of these polymers.

Preferably the poly(vinyl pyrrolidone) is only used in small quantities compared to the poly(vinyl alcohol). In a preferred embodiment of the present invention poly(vinyl pyrrolidone) is used from 0 to 10 parts by weight of the poly(vinyl alcohol) used, from 0 to 3 parts by weight being particularly preferred. Most preferred no poly(vinyl pyrrolidone)compounds are used.

In addition to the poly(vinyl alcohol) of the present invention and the optional watersoluble polymers disclosed above, the known ingredients of protective layers can be used.

Examples of known ingredients suitable for the protective layer of the present invention are surface wetting agents, coloring agents, complexants and biocides. Among said complexants, ethoxylated ethylene diamine compounds have been found to be particularly preferred for the present invention.

The protective layer has to be transparent for actinic light and preferably has a dry thickness of 0.2 to 10 g/m², 1.0 to 5 g/m² being particularly preferred. Preferably it is homogeneous, substantially impermeable to oxygen, waterpermeable, and can be washed off preferably with the conventional developer solutions used to form a printing relief after imagewise exposure of the photosensitive layer. Said photosensitive layer is removed imagewise, whereas the protective layer is removable over the entire area of the element created. The wash-off of the protective layer can be done in a separate step, but can be done during the development step as well.

The protective layer can be coated on the photosensitive layer with known techniques and the coating solution preferably contains water or a mixture of water and an organic solvent. To allow a better wetting, the coating solution preferably contains, related to the solid content, up to 10 wt. %, and particular preferred up to 5 wt. % of a surface active agent. Suitable representatives of surface active agents comprise anionic, cationic and nonionic surface active agents like sodium alkylsulfates and -sulfonates having 12 to 18 carbon atoms, an example of which is sodium dodecylsulfate, N-cetyl- and C-cetyl betaine, alkylaminocarboxylate and -dicarboxylate, and polyethylene glycols with a mean molar weight up to 400.

In addition, further functions can be added to the protective layer. For example, it can be possible to improve the safelight suitability without decreasing the sensitivity of the layer by adding a coloring agent, e.g. a water-soluble dye, that has excellent transmission to the light having a wavelength of 300 to 450 nm and that absorbs the light having a wavelength of 500 nm or more. This principle can easily be varied for different wavelengths to adjust the effective spectral sensitivity distribution of the printing plate precursor as needed.

The present invention also relates to a method of making a lithographic printing plate comprising the steps of providing a photopolymer printing plate precursor of the present invention, exposing said lithographic printing plate precursor with a laser having an emission wavelength in the range from 300 to 450 nm and processing the lithographic printing plate precursor in an aqueous alkaline developer.

In preferred embodiment of the process of the present invention the exposure is done with a laser having an emission wavelength in the range from 380 to 430 nm, in particular in the range from 390 to 420 nm, and the exposure is carried out at an energy density, measured on the surface of the plate, of 100 μJ/cm² or less.

The processing of the printing plate precursor of the present invention is done in the usual manner. After image-wise exposure a pre-heat step is performed to improve the crosslinking of the photosensitive layer. Usually the pre-heat step is then followed by the development step, wherein the complete overcoat layer and the unexposed part of the photosensitive layer are removed. The removal (wash-off) of the overcoat layer and the development of the photosensitive layer can be done in two separate steps in this order, but can also be done in one step simultaneously. Preferably the overcoat layer is washed-off with water before the development step. The wash-off can be done with cold water, but it is preferred to use hot water to accelerate the process. What remains on the support after the development step are the exposed and thereby photopolymerized parts of the photosensitive layer. The developer solution used for the development of the exposed printing plate precursors of the present invention preferably is an aqueous alkaline solution having a pH of at least 11, a pH from 11.5 to 13.5 being particularly preferred. The developer solution can contain a small percentage, preferably less than 5 wt. %, of an organic, water-miscible solvent. To adjust the pH of the solution, an alkali hydroxide is preferably used.

Examples of preferred, additional ingredients of the developer solution comprise alone or in combination alkali phosphates, alkali carbonates, alkali bicarbonates, an organic amine compound, alkali silicates, buffering agents, complexants, defoamers, surface active agents and dyes, but the suitable ingredients are not limited to the preferred examples and further ingredients can be used.

The method of development employed is not particularly limited, and may be conducted by soaking and shaking the plate in a developer, physically removing non-image portions while being dissolved in a developer by means of e.g. a brush, or spraying a developer onto the plate so as to remove non-image portions. The time for development is selected depending upon the above method used so that the non-image portions can adequately by removed, and is optionally selected within a range of 5 seconds to 10 minutes.

After the development, the plate my be subjected to a hydrophilic treatment by means of, e.g., gum arabic optionally applied to the printing plate as the case requires (gumming step).

The present invention also relates to the use of one or more types of poly(vinyl alcohol) in the protective overcoat of a photopolymer printing plate precursor, to improve the pre-heat latitude of said precursor, characterised in that the mean saponification degree of all the poly(vinyl), as is disclosed above.

### EXAMPLES

### Examples 1 to 8

### A) Preparation of the Photosensitive Layer

A composition was prepared (pw=parts per weight; wt. %=weight percentage) by mixing the ingredients as specified in table 1. This composition was coated on an electrochemically roughened and anodically oxidized aluminum sheet, the surface of which has been rendered hydrophilic by treatment with an aqueous solution of poly(vinyl phosphonic) acid (oxide weight 3 g/m²) and was dried for 2 minutes at 105° C. (circulation oven). The resulting thickness of the layer was 1.5 g/m².

TABLE 1
Composition of the photosensitive coating solution

| | Parts per |
|---|---|
| Component | weight (g) |
| A solution containing 32.4 wt. % of a methyl | 550.14 |
| methacrylate/methacrylic acid-copolymer | |
| (ratio methylmethacrylate/methacrylic acid | |
| of 4:1 by weight; acid number: 110 mg KOH/g) | |
| in 2-butanone (viscosity 105 mm²/s at 25° C.). | |
| A solution containing 88.2 wt. % of a reaction | 498.72 |
| product from 1 mole of 2,2,4-trimethyl- | |
| hexamethylenediisocyanate and 2 moles of | |
| hydroxyethylmethacrylate (viscosity 3.30 mm²/s | |
| at 25° C.) | |
| 1,4-Distyryl-3,4,5-trimethoxybenzene | 32.90 |
| Heliogene blue D 7490 ® dispersion (9.9 wt. %, | 632.89 |
| viscosity 7.0 mm²/s at 25° C.), trade name of | |
| BASF AG, as disclosed in EP 1 072 956 | |
| 2,2′-Bis(2-chlorophenyl)-4,4′,5,5′- | 49.73 |
| tetraphenyl-1,2-bisimidazole | |
| 2-Mercaptobenzothiazole | 2.30 |
| Edaplan LA 411 ® (1 wt. % in Dowanol PM ®, trade | 76.50 |
| mark of Dow Chemical Company) | |
| 2-Butanone | 2698.56 |
| Propyleneglycol-monomethylether (Dowanol PM ®, | 4046.53 |
| trade mark of Dow Chemical Company) | |
| Gamma-butyrolactone | 411.75 |

### B) Preparation/Coating of the Protective Overcoat Layer

On top of the photosensitive layer a solution in water containing 4.9 wt. % of the compositions as defined in table 2 was coated and then was dried at 110° C. for 2 minutes in a circulation oven.

TABLE 2
coating compositions of the protective overcoat; the amount
of each ingredient is listed in parts per weight (g)

| Ingredient | Ex. 1 | Ex. 2 | Ex. 3 | Ex. 4 | Ex. 5 | Ex. 6 | Ex. 7 | Ex. 8 |
|---|---|---|---|---|---|---|---|---|
| (A) | 2163.16 | 1778.16 | 1393.16 | 1063.16 | 678.16 | 293.16 | — | 1702.62 |
| (B) | — | 385.00 | 770.00 | 1100.00 | 1485.00 | 1870.00 | 2163.16 | 1486.93 |
| (C) | — | — | — | — | — | — | — | 743.47 |
| (D) | 1.44 | 1.44 | 1.44 | 1.44 | 1.44 | 1.44 | 1.44 | 2.62 |
| (E) | 2.08 | 2.08 | 2.08 | 2.08 | 2.08 | 2.08 | 2.08 | 3.79 |
| (F) | 0.18 | 0.18 | 0.18 | 0.18 | 0.18 | 0.18 | 0.18 | 0.32 |
| (G) | 3333.14 | 3333.14 | 3333.14 | 3333.14 | 3333.14 | 3333.14 | 3333.14 | 6060.25 |

(A) Partially hydrolyzed poly(vinyl alcohol) (degree of saponification 88 mol-%, viscosity 4 mPa·s in an aqueous solution of 4 wt. % at 20° C.).
(B) Fully hydrolyzed poly(vinyl alcohol) (degree of saponification 98 mol-%, viscosity 4 mPa·s in an aqueous solution of 4 wt. % at 20° C.).
(C) Partially hydrolyzed poly(vinyl alcohol) (degree of saponification 88 mol-%, viscosity 8 mPa·s in an aqueous solution of 4 wt. % at 20° C.).
(D) CA 24 E (biocide):

68% Chloroacetamide

29% Sodiumbenzoate
(E) Metolat FC 355 (ethoxylated ethylenediamine):

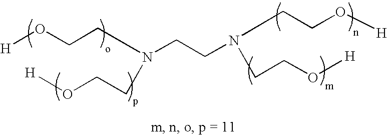

(F) Lutensol A8 (90%)(surface active agent)
(G) Water
   The protective overcoat had a dry thickness of 2.0 g/m².

### Evaluation of the Pre-Heat Latitude

Three plates were imaged with a 40% screen (110 lpi) at the appropriate exposure i.e. sensitivity of the plate. The imaging was carried out with an experimental violet platesetter device (flat bed system) equipped with a violet laser diode emitting between 392 to 417 nm. The following imaging conditions were used
Scanning speed: 1000 m/s
Variable image plane power: 0 to 10.5 mW
Spot diameter: 20 μm
Addressability: 1270 dpi

After the imaging step the plate was processed in a Agfa VSPB5 processor at a speed of 1,2 m/min. During the processing the plate is first heated (pre-heat step), next the protective overcoat is washed off and the photolayer is processed in a water based alkaline developer (Agfa EN 231C) at 28° C. After a water rinsing and gumming step the printing plate is ready to use.

The three plates were processed at different pre-heat temperatures (Tₚᵣₑ₋ₕₑₐₜ): 93° C., 104° C. and 116° C. (i.e. temperature measured at the back of the plate). The temperature at the back of the plate was varied by varying the temperature of the ceramic heater of the processor.

Next the dot area of the 40% screen (110 lpi) was measured using a Techcon DMS910. In table 3 the average of 5 measurements is listed. Next the standard deviation on the 40% screen (110 lpi) for the 3 pre-heat temperature settings (SDₚᵣₑ₋ₕₑₐₜ) was calculated. To be acceptable, the standard deviation should be less than 2, indicating a good pre-heat latitude. All results are summarised in table 3.

The examples demonstrate, that all the printing plate precursors (examples 1 to 3 and example 8) having a protective overcoat with a mean saponification degree <93 mol % have a good pre-heat latitude, while the examples 4 to 7 having a saponification degree ≧93 mol % have an unaccpetable pre-heat latitude.

TABLE 3

| | Ex. 1 | Ex. 2 | Ex. 3 | Ex. 4 | Ex. 5 | Ex. 6 | Ex. 7 | Ex. 8 |
|---|---|---|---|---|---|---|---|---|
| Mean saponification degree | 88 | 89.75 | 91.5 | 93 | 94.75 | 96.5 | 98 | 91.78 |
| (mol-%) - theoretical | | | | | | | | |
| Mean saponification degree | 87.5 | 89.5 | 91.6 | 93.3 | 94.5 | 97.2 | 98.3 | — |
| (mol-%) - experimental | | | | | | | | |
| measured via ¹³C-NMR | | | | | | | | |
| Sensitivity (μJ/cm²) | 63 | 58 | 53 | 38 | 12 | 13 | 13 | 58 |
| Tₚᵣₑ₋ₕₑₐₜ = 93° C. | 70.44 | 69.66 | 70.38 | 79.60 | 80.60 | 80.28 | 81.9 | 70.82 |
| Tₚᵣₑ₋ₕₑₐₜ = 104° C. | 69.70 | 70.04 | 70.56 | 91.46 | 95.84 | 100 | 100 | 69.08 |
| Tₚᵣₑ₋ₕₑₐₜ = 116° C. | 69.84 | 69.44 | 70.84 | 77.14 | 100 | 100 | 100 | 71.18 |
| SDₚᵣₑ₋ₕₑₐₜ | 0.39 | 0.30 | 0.23 | 7.66 | 10.21 | 11.39 | 10.45 | 1.12 |

1. A photopolymer printing plate precursor comprising in a support a photosensitive coating and a protective coating the photosensitive coating comprising a composition that is photopolymerizable upon absorption of light in the wavelength range from 300 to 450 nm, the composition comprising a binder, a polymerizable compound, a sensitizer and a photoinitiator, and the protective coating comprising one or more types of poly(vinyl alcohol) and optionally poly(vinyl pyrrolidone) in an amount of from 0 to 10 parts by weight of the one or more types of poly(vinyl alcohol), wherein said photoinitiator is a hexaaryl-bisimidazole compound, and wherein the mean saponification degree of all the polyvinylalcohols which are used in the protective coating is less than 93 mol %.

2. (canceled)

3. The photopolymer printing plate precursor according to claim 1, wherein the binder is a copolymer containing monomeric units of an α,β-unsaturated carboxylic acid and/or an α,β-unsaturated dicarboxylic acid.

4. The photopolymer printing plate precursor according to claim 1 further comprising a polyfunctional (meth)acrylate or alkyl(meth)acrylate compound as a crosslinking agent.

5. The photopolymer printing plate precursor according to claim 1, wherein the polymerizable compound comprises one or more of a urethane, a urea group or a tertiary amino group.

6. The photopolymer printing plate precursor according to claim 1, further comprising a radical chain transfer agent.

7. The photopolymer printing plate precursor according to claim 1, wherein in the sensitizer comprises an optical brightening agent.

8. The photopolymer printing plate precursor according to claim 7, wherein the optical brightening agent has a structure according to one of the following formulae: 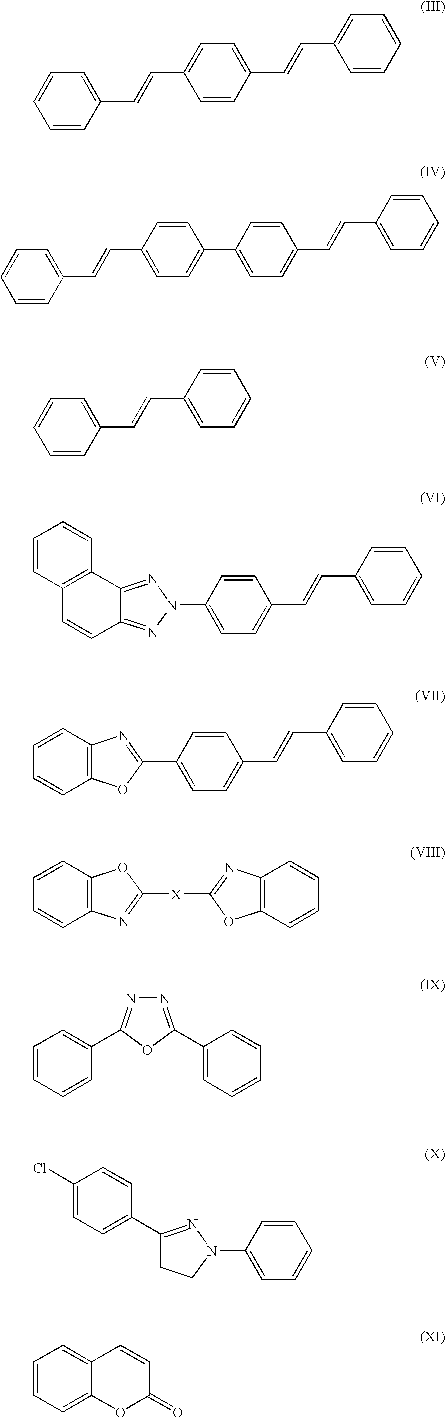 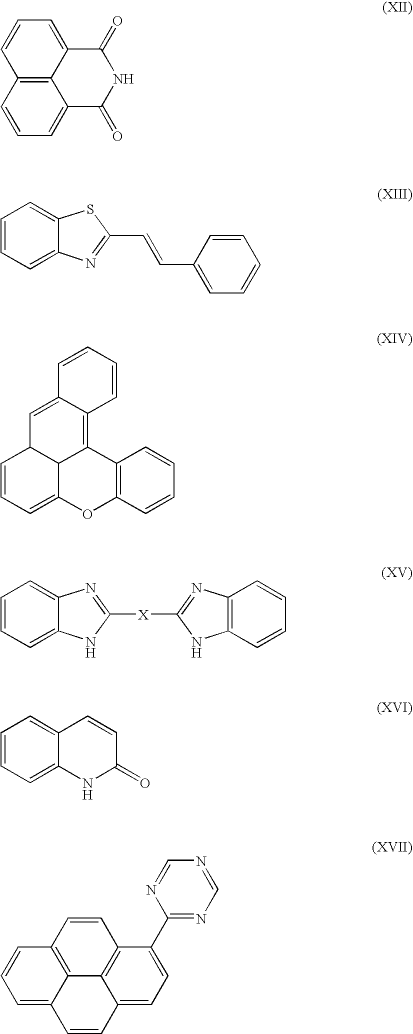
wherein X is one of the following groups, * denoting the position of attachment in the above formulae: 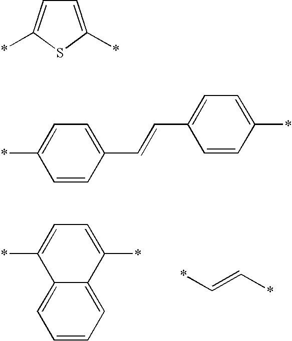
and wherein one or more of the nuclei in each of the above formulae (III) to (XVII) may be independently substituted by one or more of alkyl, alkoxy, alkylcarbonyl, alkoxycarbonyl, acyloxy, carboxyl, nitrile, amino, hydroxyl, alkylsulfonyl or aminosulfonyl.

9. A method of making a lithographic printing plate comprising the steps of providing a photopolymer printing plate precursor as defined in claim 1, exposing said printing plate precursor with a laser having an emission wavelength in the range from 300 to 450 mm and processing the printing plate precursor in an aqueous alkaline developer.

10. A method of making a lithographic printing plate comprising the steps of providing a photopolymer printing plate precursor as defined in claim 7, exposing said printing plate precursor with a laser having an emission wavelength in the range from 300 to 450 nm, and processing the printing plate precursor in an aqueous alkaline developer.

11. The method according to claim 9, wherein the exposure of the lithographic printing plate precursor is carried out at an energy density, measured on the surface of the plate, of 100 μJ/cm² or less.

12. The method according to claim 10, wherein the exposure of the lithographic printing plate precursor is carried out at an energy density, measured on the surface of the plate, of 100 μJ/cm² or less.

13. The photopolymer printing plate precursor according to claim 7, wherein the overall amount of the optical brightening agent ranges from 0.1 to 10% by weight of the photopolymerizable composition.

14. The photopolymer printing plate precursor according to claim 8, wherein the overall amount of the optical brightening agent ranges from 0.1 to 10% by weight of the photopolymerizable composition.

15. The photopolymer printing plate precursor according to claim 3, further comprising a polyfunctional (meth)acrylate or alkyl(meth)acrylate compound as a crosslinking agent.

16. The photopolymer printing plate precursor according to claim 7, further comprising a polyfunctional (meth)acrylate or alkyl(meth)acrylate compound as a crosslinking agent.

17. The photopolymer printing plate precursor according to claim 8, further comprising a polyfunctional (meth)acrylate or alkyl(meth)acrylate compound as a crosslinking agent.

18. The photopolymer printing plate precursor according to claim 13, further comprising a polyfunctional (meth)acrylate or alkyl(meth)acrylate compound as a crosslinking agent.

19. The photopolymer printing plate precursor according to claim 14, further comprising a polyfunctional (meth)acrylate or alkyl(meth)acrylate compound as a crosslinking agent.

20. The photopolymer printing plate precursor according to claim 15, wherein the polymerizable compound comprises one or more of a urethane, a urea group or a tertiary amino group.

21. The photopolymer printing plate precursor according to claim 16, wherein the polymerizable compound contains one or more of a urethane, a urea group or a tertiary amino group.

22. The photopolymer printing plate precursor according to claim 17, wherein the polymerizable compound contains one or more of a urethane, a urea group or a tertiary amino group.

23. The photopolymer printing plate precursor according to claim 18, wherein the polymerizable compound contains one or more of a urethane, a urea group or a tertiary amino group.

24. The photopolymer printing plate precursor according to claim 19, wherein the polymerizable compound comprises one or more of a urethane, a urea group or a tertiary amino group

25. The photopolymer printing plate precursor according to claim 20, further comprising a radical chain transfer agent.

26. The photopolymer printing plate precursor according to claim 21, further comprising a radical chain transfer agent.

27. The photopolymer printing plate precursor according to claim 22, further comprising a radical chain transfer agent.

28. The photopolymer printing plate precursor according to claim 23, further comprising a radical chain transfer agent.

29. The photopolymer printing plate precursor according to claim 24, further comprising a radical chain transfer agent.

30. A method of making a lithographic printing plate comprising the steps of providing a photopolymer printing plate precursor as defined in claim 13, exposing the printing plate precursor, and processing the exposed printing plate precursor, wherein the exposure of the lithographic printing plate precursor is carried out at an energy density, measured on the surface of the plate, of 100 μJ/cm² or less.

31. A method of making a lithographic printing plate comprising the steps of providing a photopolymer printing plate precursor as defined in claim 14, exposing the printing plate precursor, and processing the exposed printing plate precursor, wherein the exposure of the lithographic printing plate precursor is carried out at an energy density, measured on the surface of the plate, of 100 μJ/cm² or less.

32. A method of making a lithographic printing plate comprising the steps of providing a photopolymer printing plate precursor as defined in claim 28, exposing the printing plate precursor, and processing the exposed printing plate precursor, wherein the exposure of the lithographic printing plate precursor is carried out at an energy density, measured on the surface of the plate, of 100 μJ/cm² or less.

33. A method of making a lithographic printing plate comprising the steps of providing a photopolymer printing plate precursor as defined in claim 29, exposing the printing plate precursor, and processing the exposed printing plate precursor, wherein the exposure of the lithographic printing plate precursor is carried out at an energy density, measured on the surface of the plate, of 100 μJ/cm² or less.
